(19) United States
(12) Patent Application Publication
(10) Pub. No.: US 2026/0094789 A1
(43) Pub. Date: Apr. 2, 2026

(54) Simplified Gas Delivery System for Atomic Layer Etching

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/904,028

(22) Filed: Oct. 1, 2024

(51) Int. Cl. H01J 37/32; H01L 21/67

(52) U.S. Cl. CPC H01J 37/32449; H01J 37/32816; H10P 72/0421; H01J 2237/334

(57) ABSTRACT

Disclosed herein is a cost-effective atomic layer etching (ALE) system and method, featuring a simplified and rapid gas delivery system. The system reduces overall costs by eliminating the need for a gasbox and a manometer. Preset mass flow controllers (MFCs) and three-way valves precisely manage gas flow during both the surface modification and sputtering steps of the ALE process. By leveraging the self-limiting nature of ALE, the system enhances efficiency by controlling only the volume of delivered gases, without requiring steady-state chamber pressures.

### FIELD OF THE INVENTION

The present invention relates to systems and methods for atomic layer etching (ALE), with a particular focus on a simplified gas delivery system that reduces overall costs and improves the efficiency of ALE processes.

### BACKGROUND OF THE INVENTION

Reactive ion etching (RIE) is a widely used technology in semiconductor manufacturing. In RIE, multiple species, including neutrals, radicals, and ions, interact with the etching process. A defining feature of RIE is the synergistic interaction between ion and neutral fluxes, which enhances the etching rate. This phenomenon was first described by Coburn and Winters in their work “Ion-and electron-assisted gas-surface chemistry—an important effect in plasma etching,” published in Journal of Applied Physics, vol. 50, pages 3189-3196 (1979). They observed increased silicon etching rates when using a combination of an argon ion beam and a XeF2 neutral beam.

Effective RIE relies on balancing ion and neutral fluxes to maximize this synergy. However, as semiconductor dimensions shrink to the nanometer scale, particularly in high aspect ratio structures, maintaining this balance has become increasingly challenging. Additionally, achieving uniform results across large wafers, such as 300 mm wafers, while ensuring repeatability in production, has become more difficult. ALE was developed to address some of these limitations. Although ALE systems have evolved from RIE systems and face fewer uniformity challenges for large wafers, ALE has unique requirements due to the nature of its process steps. An overview of ALE is provided by Karanik et al. in “Overview of atomic layer etching in the semiconductor industry” (Journal of Vacuum Science & Technology A, vol. 33, pages 020802 1-14, 2015) and further explored by Lill in “Atomic Layer Processing: Semiconductor Dry Etching Technology” (Wiley-VCH GmbH, 2021). ALE allows for the controlled removal of material layers with atomic-level precision through sequential self-limiting reactions.

The basic ALE process includes two primary steps: surface modification and material removal. During the modification step, a thin reactive layer is created, which is easier to remove than the underlying unmodified material. The removal step eliminates this reactive layer while preserving the underlying substrate. Material removal can be facilitated using thermal energy or ion bombardment. Thermal removal methods are described in U.S. Pat. No. 10,208,383 to George et al., while removal via ion bombardment is discussed in U.S. Pat. No. 10,727,073 to Tan et al.

Despite its advantages, conventional ALE systems tend to operate slowly, primarily due to complex and costly gas delivery mechanisms. Thus, there is a need for a more cost-effective and efficient gas delivery system that meets or exceeds current performance standards.

### SUMMARY OF THE INVENTION

The present invention introduces an ALE system with a simplified gas delivery system that reduces operational costs and increases processing speed. The ALE process, particularly anisotropic ALE, comprises two distinct steps. In the first step, surface modification is achieved by introducing a first gas, such as chlorine, into the chamber to modify the substrate surface and weaken chemical bonds in the material to be etched. Plasma can be generated to accelerate this step by creating chemically reactive neutrals.

In the second step, a sputtering process is used to remove the modified layer. A second gas, such as argon, is introduced into the chamber after the first gas is expelled. Plasma-generated ions are accelerated towards the substrate by applying a bias, removing the modified layer.

In certain embodiments, the first and second gases are sourced directly from the facility's gas supply, eliminating the need for a separate gasbox. During the surface modification step, the flow of the first gas is controlled by a mass flow controller (MFC) and introduced into the gas distribution unit of the chamber via a three-way valve. This valve directs the first gas either into the chamber or to a divert line. An atomic layer deposition (ALD) valve is recommended for its rapid switching capabilities, measured in milliseconds. The second gas is managed similarly during the sputtering step.

In some embodiments, the use of a manometer is omitted entirely. The total quantity of the first gas for the chemical modification step is controlled by adjusting the flow rate and duration of the step. Likewise, the total quantity of the second gas for the sputtering step is regulated.

This invention departs from the traditional goal of maintaining a steady-state chamber pressure and instead takes advantage of the self-limiting behaviors inherent in the ALE process during both the surface modification and sputtering steps. This approach increases the speed of the ALE process without sacrificing performance.

### BRIEF DESCRIPTIONS OF THE DRAWINGS

For enhanced clarity, the following description refers to accompanying drawings:

FIG. 1: Illustrates a conventional ALE process system.

FIG. 2: Depicts a flowchart of a conventional ALE process.

FIG. 3: Shows an exemplary ALE process system featuring a simplified gas delivery system.

FIG. 4: Details the steps involved in the ALE process using the simplified gas delivery system.

### DETAILED DESCRIPTION

To provide a comprehensive understanding, the following description expands on particular embodiments of the present invention. While specific details are provided for clarity, variations and adaptations that fall within the scope of the appended claims are considered to be within the spirit of the invention. Descriptions of conventional methods and components are included where necessary to highlight the unique aspects of this invention.

### DEFINITION OF TERMS

Aspect Ratio: The ratio of height to width of a feature on a semiconductor wafer, which is critical in defining the geometry and performance of microstructures.

Bias Unit: A component that generates both plasma and bias voltage to accelerate ions toward the wafer, which is held in place by an electrostatic chuck (ESC). This voltage creates an electric field that enhances ion bombardment, controlling ion energy and directionality, essential for processes like etching.

Chamber: A sealed environment in semiconductor manufacturing equipment where processes such as etching, or deposition occur.

Chuck: A device used in semiconductor manufacturing equipment to securely hold the wafer during processing.

Electrostatic Chuck (ESC): A type of chuck that uses electrostatic forces to hold a substrate in place during semiconductor processes, ensuring uniform clamping and stability.

Gas Distribution Unit: A component within a plasma process chamber that introduces and distributes process gases. This unit may take various forms, such as a central or angled injecting points, or a showerhead featuring a perforated plate to disperse gas across the substrate. Side injection mechanisms can also introduce gas from the chamber's sides to promote lateral gas flow.

Gas Pressure Regulator: A device that controls and stabilizes gas pressure, ensuring precise conditions for processes like etching and deposition. It maintains consistent downstream pressure despite fluctuations in supply or flow rate.

Facility Gas Supply: The source of process gases used in a vacuum process chamber, typically connected to a facility's centralized gas distribution system. A gasbox regulates and controls the flow of gases to ensure the correct composition and purity.

Anisotropic Atomic Layer Etching (ALE): a precise etching process used in semiconductor manufacturing that removes material layer by layer at the atomic scale, allowing precise control over etch depth and profile. ALE operates in cycles, with each cycle consisting of a surface modification step and a sputtering step. In the surface modification step, the material is chemically altered to form a reactive layer. This layer is selectively removed during the sputtering step by ion bombardment, offering high precision and selectivity.

Plasma Process Chamber: A specialized vacuum chamber used in semiconductor manufacturing for plasma-based processes such as etching and deposition. Plasma provides the necessary energy to activate chemical reactions or remove material from the wafer surface.

Plasma Source: A device that generates plasma for semiconductor processes like etching, deposition, and surface modification. Common types include inductively coupled plasma (ICP), transformer coupled plasma (TCP), and capacitively coupled plasma (CCP). ICP uses a radio frequency (RF) magnetic field from a coil to generate plasma, TCP creates plasma through transformer action using a planar coil and RF energy, and CCP generates plasma by applying RF power across two electrodes.

Process System: The equipment and machinery used in semiconductor manufacturing for processes such as deposition, etching, and cleaning.

Reactive Ion Etching (RIE): A plasma-based etching technique where both ion bombardment and chemical reactions remove material from a substrate. In RIE, reactive gas is ionized in plasma, creating ions and neutral species. Ions are accelerated toward the substrate by an electric field, physically sputtering the material, while reactive neutrals enhance chemical etching.

Resonator: A circuit component designed to resonate at a specific radio frequency, often used for impedance matching in RF circuits. Resonators are constructed using various technologies, such as LC (inductor-capacitor) circuits, and provide high selectivity and stability at their resonant frequency.

RF Power Generator: A device that generates radio frequency power used to energize plasma for processes like etching and deposition.

Substrate: The base material, typically a silicon wafer, upon which semiconductor devices are fabricated.

System Controller: The central unit that manages and controls the operations and parameters of plasma process systems, ensuring coordinated and efficient functioning.

Tailored Waveform Generator: A device that produces custom-designed electrical waveforms for optimizing plasma processes. By adjusting waveform shape, frequency, and amplitude, it allows precise control over plasma characteristics, improving the uniformity, performance, and selectivity of etching and deposition processes.

Transmission Line (RF): A conductor designed to carry RF signals with minimal loss. In semiconductor manufacturing, transmission lines are used to transfer RF power from the generator to the plasma source, assisting in impedance matching to minimize reflections and power loss.

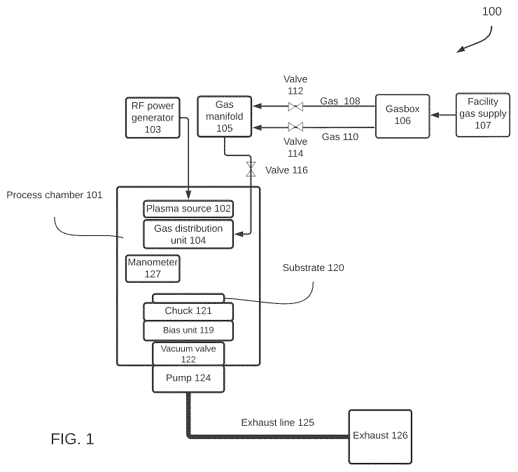

FIG. 1 illustrates a conventional atomic layer etching (ALE) process system, identified as 100. The system includes a plasma process chamber 101 housed within a vacuum environment. The chamber 101 is equipped with a plasma source 102, energized by an RF power generator 103. The plasma source 102 can be configured as transformer-coupled plasma (TCP) or inductively coupled plasma (ICP). In some configurations, a matching network, such as a resonator (not shown), may be positioned between the RF power generator 103 and the plasma source 102 to match the impedance between the RF power generator output and the plasma load in the chamber 101, considering the impact of transmission lines. In other configurations, a direct connection may be employed.

The system also includes a gas distribution unit 104 that draws gases from a gasbox 106 through a gas manifold 105. The gas distribution unit 104 can be configured as a showerhead or injector, depending on the specific design requirements. The manifold 105 combines gases from different lines before introducing them into the chamber 101. Valves 112 and 114 control the flow of gases 108 and 110 from the gasbox 106 to the manifold 105, while valve 116 regulates the flow of gases from the manifold 105 to the distribution unit 104. Although the illustration only shows two gas lines for simplicity, multiple gases may be involved in various ALE processes. The gasbox 106 is connected to a facility gas supply 107.

Inside the chamber 101, a chuck 121 supports a substrate 120. The chuck 121 is typically an electrostatic chuck (ESC), particularly suitable for etching applications. To ensure optimal ion energy, especially for etching high aspect ratio structures, a bias unit 119 is activated when plasma is ignited in the chamber. The bias unit may receive power from an RF power generator connected to the chuck 121 via a blocking capacitor, or it may come from a tailored waveform generator, depending on system design specifications.

Gases and reaction by-products are evacuated from the chamber 101 by a pump 124. A vacuum valve 122, located near the pump, controls the rate of gas evacuation, which is directed to an exhaust 126 via an exhaust line 125. The steady-state pressure within the chamber is maintained by balancing the rates of gas injection and extraction, with pressure readings taken by a manometer 127 and managed using a proportional-integral-derivative (PID) control loop.

In a typical ALE process, two different gases are used over two distinct steps—the surface modification step and the sputtering step—commonly referred to as two half-cycles, which together form a complete ALE cycle.

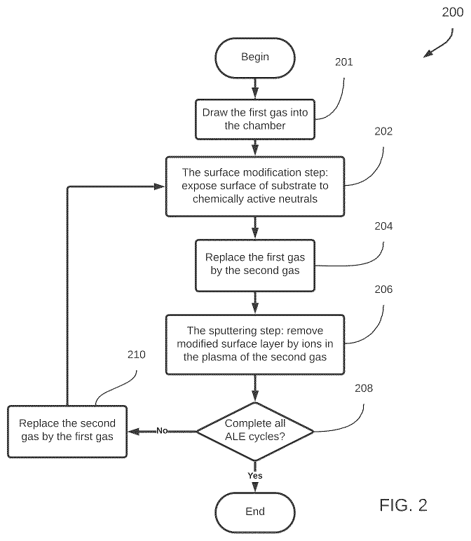

FIG. 2 illustrates a conventional ALE process flow, labeled 200. Step 201 begins by introducing the first gas 108 from the gasbox 106 into the chamber 101 through the gas distribution unit 104. In Step 202, the first gas chemically modifies the surface of the substrate 120. For example, chlorine gas can be used to form silicon-chlorine bonds that are weaker than the underlying silicon-silicon bonds. The plasma generated by the RF power generator 103 and plasma source 102 may assist in this chemical alteration. During this step, the bias unit of the chuck is disengaged to minimize ion bombardment of the substrate surface.

Step 204 signals the end of the surface modification step, at which point the supply of the first gas 108 is stopped, and the second gas 110 (typically an inert gas) is introduced into the chamber 101. In Step 206, the modified layer is removed through ion bombardment during the sputtering step, where ions generated from the second gas are accelerated by the bias unit 119 to remove the modified layer.

Given that each ALE cycle removes only a few monolayers of material, multiple cycles are required to achieve the desired etch depth. In some cases, the number of ALE cycles may exceed one hundred, especially for etching high aspect ratio structures. Step 208 involves counting the cycles and comparing them to a predefined recipe. If the target number of cycles is reached, the process is complete. Otherwise, in Step 210, the second gas is replaced with the first, initiating a new ALE cycle. A delay may be introduced between gas transitions to prevent unintended reactive ion etching (RIE) effects.

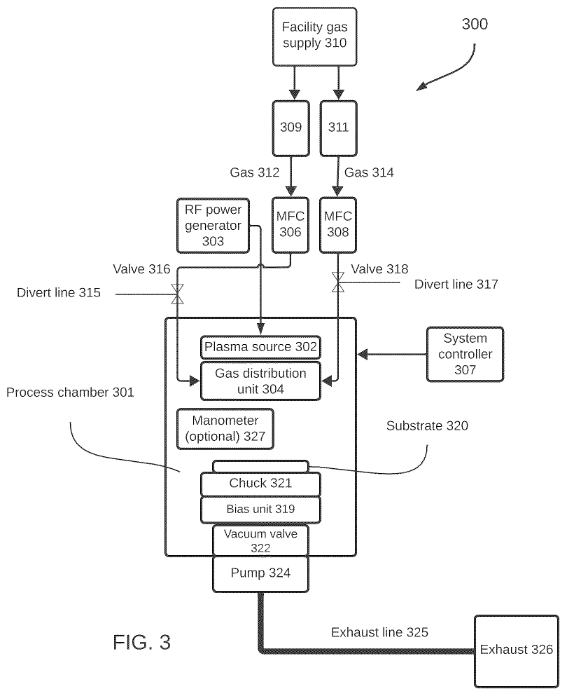

FIG. 3 illustrates an embodiment of an ALE process system, designated as 300, which features a simplified gas delivery system. This embodiment introduces several notable differences compared to the conventional ALE process system 100. One key difference is the elimination of the gasbox, which reduces system costs, as the gasbox is a relatively expensive component in the ALE process system. Additionally, the manometer 327 becomes optional and may be removed in some embodiments. Traditionally, the manometer was used to measure vacuum pressure within the chamber and worked in conjunction with the pump and valve to achieve stable pressure for the etching process, typically managed by a PID control.

In this embodiment, a new approach is adopted, shifting the control strategy from stabilizing chamber pressure to regulating the total volume of gas introduced into the chamber during the surface modification and sputtering steps. The total volume of gas is determined by both the gas flow rate and the duration of gas introduction into the chamber.

The ALE process inherently exhibits self-limiting properties in both the surface modification and sputtering steps. For example, once a sufficient quantity of chemically active neutrals is adsorbed onto the substrate surface, further modification ceases. Similarly, the sputtering step has a relatively stable process window, where increasing ion energy or density does not significantly accelerate material removal. These self-limiting characteristics allow for cost reduction without sacrificing performance.

The ALE process system 300 includes a plasma process chamber 301 capable of maintaining a vacuum environment. The chamber 301 is equipped with a plasma source 302 connected to an RF power generator 303. A gas distribution unit 304, which can take the form of a showerhead or injector, draws gases directly from a facility gas supply 310, eliminating the need for a gasbox. The first gas 312 flows through a first MFC 306 and a first three-way valve 316 into the gas distribution unit 304. The three-way valve 316 can direct the gas into the chamber, divert it to a first line 315, or close the flow. A first gas pressure regulator 309 is located between the facility gas supply 310 and the MFC 306 to ensure proper gas pressure.

The MFC 306 controls the flow rate of the gas 312, but due to its inherent latency, it requires tens of milliseconds to reach a designated flow rate by engaging a MFC internal PID control. In one implementation, the set point for the flow rate, such as a solenoid coil current, can be predetermined during setup and stored for future use. In another implementation, the flow rates of the MFCs are stabilized before the ALE process begins and remain steady throughout the process.

Similarly, a second gas pressure regulator 311 is placed between a second MFC 308 and the facility gas supply 310. The second three-way valve 318 directs the second gas 314 either into the chamber or to a second divert line 317.

ALD valves are recommended for their rapid switching capabilities, measured in milliseconds. In some implementations, various combinations of valves can be employed as known in the art.

The system controller 307 coordinates and regulates the ALE process system 300. It interprets the process recipe to determine the gas flow rates and oversees the operation of the valves 316 and 318, providing pulsed electrical signals to control their timing. The controller 307 also manages the initiation and termination of the ALE process.

A chuck 321, often an electrostatic chuck (ESC), is positioned in the lower portion of the chamber 301 to hold the substrate 320 during processing. For processes involving high aspect ratio structures, a bias unit 319 is used to provide higher ion energy, which may be powered by an RF generator or a tailored waveform generator.

The gases and reaction by-products are evacuated from the chamber 301 via a pump 324 through a vacuum valve 322. Unlike conventional systems that rely on achieving steady-state chamber pressure, this embodiment does not require a manometer. However, the vacuum valve set point may be determined during setup and controlled by the system controller 307.

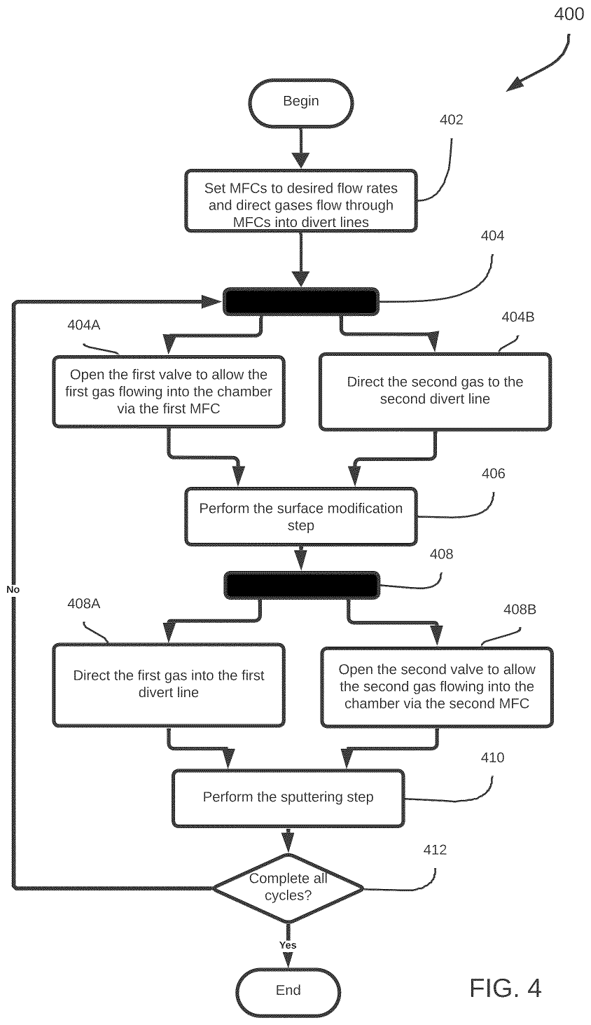

FIG. 4 provides a detailed process flow 400 for the ALE process system 300. In Step 402, before initiating the ALE process, the MFCs 306 and 308 are preset to flow rates specified in the process recipe. These flow rates may be achieved by directly generating solenoid coil currents for the MFCs without using the internal PID controls, or by operating the MFCs to reach steady states before processing begins. The gases are initially directed to divert lines 315 and 317.

Step 404 involves two parallel sub-steps: 404A and 404B. In sub-step 404A, the three-way valve 316 opens, allowing gas 312 to flow into the chamber 301 at a rate predetermined by the MFC 306. The total volume of gas is calculated based on the flow rate and the duration for which the valve 316 remains open, controlled by pulsed electrical signals from the system controller 307. Simultaneously, in sub-step 404B, the second three-way valve 318 directs gas 314 to the divert line 317.

Step 406 marks the surface modification step, during which the substrate surface undergoes chemical alterations, weakening the bonds in the material to be etched.

In Step 408, the system performs two simultaneous sub-steps: 408A and 408B. In sub-step 408A, valve 316 redirects gas 312 to the divert line 315, and in sub-step 408B, valve 318 channels gas 314 into the chamber for the sputtering step. These sub-steps may occur simultaneously or with a delay, controlled by the system controller 307, to ensure complete evacuation of the first gas.

Step 410 represents the sputtering step, during which the chemically modified surface is removed by energetic ions generated by the plasma and bias unit. Following this, the ALE cycle is completed, and the second gas 314 is evacuated from the chamber while the first gas 312 is reintroduced for the next cycle.

Finally, in Step 412, the system controller 307 evaluates whether the required number of ALE cycles has been completed. If the process is incomplete, the cycle repeats. Otherwise, the process concludes.

The inventive concept can readily be extended to other process systems such as ALD process systems, or other thermal process systems, or any process system, where rapid switching of gases or precursors is required.

1. A process system, comprising:
a plasma process chamber configured for a vacuum environment;
a plasma source operatively coupled to an RF power generator;
a gas delivery system comprising
a facility gas supply;
a gas distribution unit for distributing a gas drawn from the facility gas supply into the chamber;
a first MFC and a first valve placed sequentially between the facility gas supply and the gas distribution unit for delivering a first gas, wherein the first valve can deliver the first gas to the chamber, to a first divert line, or be closed;
a second MFC and a second valve placed sequentially between the facility gas supply and the gas distribution unit for delivering a second gas, wherein the second valve can deliver the second gas to the chamber, to a second divert line, or be closed; and
a system controller configured to execute an ALE process with multiples cycles, each cycle including a surface modification step followed by a sputtering step, wherein the system controller is further configured to
operate the first valve to deliver the first gas into the chamber through the gas distribution unit during the surface modification step and operate the second valve to direct the second gas to the second divert line, and
operate the second valve to deliver the second gas into the chamber through the gas distribution unit during the sputtering step and operate the first valve to direct the first gas into the first divert line,
wherein the first MFC and the second MFC are preset to designated flow rates for the first and the second gases prior to commencing ALE processing and remain unchanged during the ALE processing.

2. The system of claim 1, further comprises a first gas pressure regulator and a second gas pressure regulator configured to regulate the first and the second gases, respectively.

3. The system of claim 2, wherein the system is configured without a gasbox.

4. The system of claim 1, wherein the system controller is configured to execute the ALE process without achieving a steady-state chamber pressure, wherein a manometer for measuring the chamber pressure is absent.

5. The system of claim 1, wherein the first valve and the second valve are ALD valves.

6. The system of claim 1, wherein the first and the second valves are controlled by the system controller via pulsed electrical signals.

7. The system of claim 6, wherein the signal for stopping the flow of first gas to the chamber and the signal for introducing the second gas into the chamber are synchronized.

8. The system of claim 6, wherein the signal for stopping the flow of the first gas to the chamber and the signal for introducing the second gas into the chamber are asynchronized, with a delay introduced to allow the first gas to be evacuated from the chamber.

9. The system of claim 6, wherein the signal for stopping the flow of the second gas to the chamber and the signal for introducing the first gas into the chamber are synchronized.

10. The system of claim 6, wherein the signal for stopping the flow of the second gas to the chamber and the signal for introducing the first gas into the chamber are asynchronized, wherein a delay is introduced to allow the second gas is evacuated from the chamber.

11. The system of claim 1, wherein the first MFC, the second MFC, and a vacuum valve have set points determined during a set up procedure, and wherein these set points remain unchanged throughout the ALE processing.

12. The system of claim 1, wherein the first MFC, the second MFC, and a vacuum valve include PID controls, and wherein the PID controls remain deactivated throughout the ALE processing.

13. The system of claim 11, wherein the set points for the MFCs include solenoid coil currents.

14. A gas delivery system for an ALE process system, comprising:
a first MFC and a second MFC preset to predetermined flow rates for a first gas and a second gas, wherein set points for the MFCs remain unchanged throughout ALE processing;
a first three-way valve and a second three-way valve configured to direct one gas to a process chamber while directing another gas to a divert line; and
a first pressure regulator and a second gas pressure regulator to maintain the first and the second gases at designated pressures before entering the MFCs.

15. The gas delivery system of claim 14, wherein the system is operated for the ALE processing without achieving a steady-state chamber pressure, thereby eliminating a manometer in the process chamber.

16. The gas delivery system of claim 14, wherein a gasbox is absent.

17. The gas delivery system of claim 14, wherein said system controller is configured to provide pulsed electrical signals to the three-way valves to control their operations.

18. The gas delivery system of claim 14, wherein the first MFC, the second MFC, and a vacuum valve further include set points, wherein the set points are determined during a set up procedure, wherein the set points remain unchanged during the ALE processing.

19. The gas delivery system of claim 14, wherein the first MFC, the second MFC, and a vacuum valve further include PID controls, wherein the PID controls remain deactivated during the ALE processing.

20. The gas delivery system of claim 18, wherein the set points for the MFCs include solenoid coil currents.
